(19) United States
(12) Patent Application Publication
(10) Pub. No.: US 2014/0252310 A1
(43) Pub. Date: Sep. 11, 2014

(54) SEMICONDUCTOR LIGHT EMITTING DEVICE AND METHOD FOR MANUFACTURING SAME

(71) Applicant: Kabushiki Kaisha Toshiba, Minato-ku (JP)

(72) Inventors: Hiroshi ONO, Tokyo (JP); Satoshi Mitsugi, Kanagawa-ken (JP); Hiroshi Katsuno, Tokyo (JP); Naoharu Sugiyama, Kanagawa-ken (JP); Shinya Nunoue, Chiba-ken (JP)

(73) Assignee: Kabushiki Kaisha Toshiba, Minato-ku (JP)

(21) Appl. No.: 14/169,693

(22) Filed: Jan. 31, 2014

(30) Foreign Application Priority Data
Mar. 8, 2013 (JP) 2013-047253

(51) Int. Cl. H01L 33/06; H01L 33/58; H01L 33/30

(52) U.S. Cl. CPC H01L 33/06; H01L 33/30; H01L 33/58
USPC 257/13; 438/29

(57) ABSTRACT

A semiconductor light emitting device includes a stacked body and an optical member. The stacked body includes a first semiconductor layer, a second semiconductor, and a light emitting layer. The second semiconductor layer is separated from the first semiconductor layer in a first direction. The light emitting layer is provided between the first semiconductor layer and the second semiconductor layer. The optical member is stacked with the stacked body in the first direction. The optical member is light-transmissive. The length of the optical member in the first direction is longer than a length of the first semiconductor layer in the first direction. The surface area of the optical member projected onto a plane perpendicular to the first direction is less than a surface area of the stacked body projected onto the plane.

### CROSS-REFERENCE TO RELATED APPLICATIONS

This application is based upon and claims the benefit of priority from Japanese Patent Application No. 2013-047253, filed on Mar. 8, 2013; the entire contents of which are incorporated herein by reference.

### FIELD

Embodiments described herein relate generally to a semiconductor light emitting device and a method for manufacturing same.

### BACKGROUND

Semiconductor light emitting devices include light emitting diodes, laser diodes, etc. In such a semiconductor light emitting device, for example, a buffer layer is provided between a crystal growth substrate and a semiconductor crystal layer. For example, the buffer layer relaxes the lattice mismatch between the substrate and the crystal layer and suppresses the warp of the crystal layer and the substrate. The buffer layer is removed, for example, after adhering the crystal layer to another supporting substrate. In such a case, warp and/or cracks may undesirably occur in the crystal layer. In the case where the buffer layer remains, the occurrence of warp and/or cracks can be suppressed even after the crystal layer is adhered to the supporting substrate. However, in the case where the buffer layer remains, a portion of the light emitted from the crystal layer is undesirably absorbed by the buffer layer. For example, the light extraction efficiency undesirably decreases.

### BRIEF DESCRIPTION OF THE DRAWINGS

FIG. 1A to FIG. 1C are schematic views showing a semiconductor light emitting device according to a first embodiment;

FIG. 2 is a schematic cross-sectional view showing a portion of the semiconductor light emitting device according to the first embodiment;

FIG. 3A and FIG. 3B are schematic views showing the workpiece according to the first embodiment;

FIG. 4A to FIG. 4H are schematic plan views showing other semiconductor light emitting devices according to the first embodiment;

FIG. 5A to FIG. 5E are schematic views showing the results of optical simulations of the semiconductor light emitting device according to the first embodiment;

FIG. 6A to FIG. 6F are schematic views showing the results of stress simulations of the semiconductor light emitting device according to the first embodiment;

FIG. 7A to FIG. 7C are schematic cross-sectional views showing the method for manufacturing the semiconductor light emitting device according to the first embodiment;

FIG. 8A to FIG. 8C are schematic cross-sectional views showing the method for manufacturing the semiconductor light emitting device according to the first embodiment;

FIG. 9A and FIG. 9B are schematic cross-sectional views showing the method for manufacturing the semiconductor light emitting device according to the first embodiment;

FIG. 10 is a schematic plan view showing another semiconductor light emitting device according to the first embodiment;

FIG. 11 is a graph showing an example of characteristics of the semiconductor light emitting device according to the first embodiment;

FIG. 12A to FIG. 12C are schematic views showing another semiconductor light emitting device according to the first embodiment;

FIG. 13 is a schematic cross-sectional view showing another semiconductor light emitting device according to the first embodiment; and

FIG. 14 is a flowchart showing a method for manufacturing a semiconductor light emitting device according to a second embodiment.

### DETAILED DESCRIPTION

According to one embodiment, a semiconductor light emitting device includes a stacked body and an optical member. The stacked body includes a first semiconductor layer, a second semiconductor, and a light emitting layer. The first semiconductor layer is of a first conductivity type. The second semiconductor layer is of a second conductivity type and is separated from the first semiconductor layer in a first direction. The light emitting layer is provided between the first semiconductor layer and the second semiconductor layer. The optical member is stacked with the stacked body in the first direction. The optical member is light-transmissive. The length of the optical member in the first direction is longer than a length of the first semiconductor layer in the first direction. The surface area of the optical member projected onto a plane perpendicular to the first direction is less than a surface area of the stacked body projected onto the plane. At least a portion of the optical member includes Al. An Al composition ratio of the at least a portion of the optical member is higher than an Al composition ratio of the stacked body.

According to another embodiment, a method is disclosed for manufacturing a semiconductor light emitting device. The method can include preparing a workpiece. The workpiece includes a growth substrate, a stacked film, and a buffer unit. The stacked film is provided on the growth substrate. The stacked film includes a first semiconductor, a second semiconductor, and a light emitting film. The first semiconductor film is of a first conductivity type. The second semiconductor film is of a second conductivity type and is separated from the first semiconductor film in a stacking direction of the growth substrate and the stacked film. The light emitting film is provided between the first semiconductor film and the second semiconductor film. The buffer unit is provided between the growth substrate and the stacked film. At least a portion of the buffer unit includes Al. An Al composition ratio of the at least a portion of the buffer unit is higher than an Al composition ratio of the stacked film. The method can include removing the growth substrate. The method can include forming an optical member from the buffer unit. A length of the optical member in the stacking direction is longer than a length of the first semiconductor film in the stacking direction. A surface area of the optical member projected onto a plane perpendicular to the stacking direction is less than a surface area of the stacked film projected onto the plane. At least a portion of the optical member includes Al. An Al composition ratio of the at least a portion of the optical member is higher than an Al composition ratio of the stacked film.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

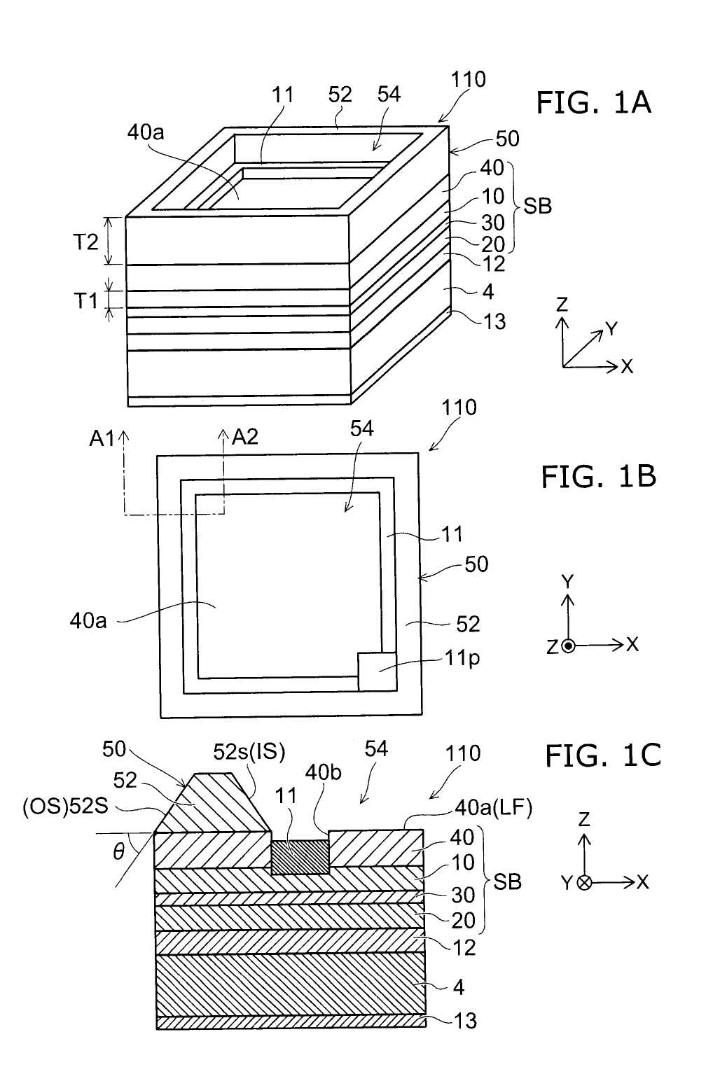

FIG. 1A to FIG. 1C are schematic views showing a semiconductor light emitting device according to a first embodiment.

FIG. 1A is a schematic perspective view; FIG. 1B is a schematic plan view; and FIG. 1C is a schematic cross-sectional view showing a cross section along line A1-A2 of FIG. 1B.

As shown in FIG. 1A to FIG. 1C, the semiconductor light emitting device 110 according to the embodiment includes a stacked body SB and an optical layer 50.

The stacked body SB includes a first semiconductor layer 10, a second semiconductor layer 20, and a light emitting layer 30.

The first semiconductor layer 10 includes a nitride semiconductor and is a first conductivity type. For example, the first conductivity type is an n type; and the second conductivity type is a p type. The first conductivity type may be the p type; and the second conductivity type may be the n type. Hereinbelow, the case is described where the first conductivity type is the n type and the second conductivity type is the p type. The first semiconductor layer 10 includes, for example, a GaN layer including an n-type impurity. The n-type impurity includes, for example, Si.

The second semiconductor layer 20 is separated from the first semiconductor layer 10 in a first direction. In the example, the first direction is taken as a Z-axis direction. The first direction is, for example, a direction perpendicular to the film surface of the first semiconductor layer 10. One direction perpendicular to the Z-axis direction is taken as an X-axis direction. A direction perpendicular to the Z-axis direction and the X-axis direction is taken as a Y-axis direction.

The second semiconductor layer 20 includes a nitride semiconductor and is the second conductivity type. The second semiconductor layer 20 includes, for example, a GaN layer including a p-type impurity. The p-type impurity includes, for example, Mg. For example, the thickness of the second semiconductor layer 20 is thinner than the thickness of the first semiconductor layer 10. The thickness of the second semiconductor layer 20 may be equal to or greater than the thickness of the first semiconductor layer 10.

The light emitting layer 30 is provided between the first semiconductor layer 10 and the second semiconductor layer 20. For example, the Z-axis direction (the first direction) corresponds to the stacking direction of the first semiconductor layer 10, the second semiconductor layer 20, and the light emitting layer 30. In the example, the light emitting layer 30 is provided on the second semiconductor layer 20; and the first semiconductor layer 10 is provided on the light emitting layer 30.

For example, the light emitting layer 30 includes a nitride semiconductor. The light emitting layer 30 includes, for example, multiple barrier layers, and a well layer provided between the multiple barrier layers. The barrier layers and the well layers are stacked along the Z-axis direction. The light emitting layer 30 has, for example, a MQW (Multi-Quantum Well) structure. The light emitting layer 30 may have a SQW (Single-Quantum Well) structure. The barrier layer includes, for example, a GaN layer. The well layer includes, for example, an InGaN layer.

A current is caused to flow in the light emitting layer 30 by applying a voltage between the first semiconductor layer 10 and the second semiconductor layer 20. Thereby, light is emitted from the light emitting layer 30.

The optical layer 50 is stacked with the stacked body SB in the Z-axis direction. The optical layer 50 is light-transmissive. The optical layer 50 is light-transmissive to the light emitted from the light emitting layer 30. The optical layer 50 includes an optical member 52. The optical member 52 is stacked with the stacked body SB in the Z-axis direction and is light-transmissive. The optical member 52 extends in a direction perpendicular to the Z-axis direction. The optical member 52 extends, for example, in a direction parallel to the X-Y plane. A length T2 of the optical member 52 in the Z-axis direction is longer than a length T1 of the first semiconductor layer 10 in the Z-axis direction. In other words, the thickness of the optical member 52 is thicker than the thickness of the first semiconductor layer 10. The surface area of the optical member 52 projected onto a plane (the X-Y plane) perpendicular to the Z-axis direction is less than the surface area of the stacked body SB projected onto the X-Y plane. The surface area of the optical member 52 projected onto the X-Y plane is less than, for example, the surface area of the first semiconductor layer 10 projected onto the X-Y plane.

In the example, the optical member 52 has a frame-like configuration. The configuration of the optical member 52 projected onto the X-Y plane is, for example, a quadrilateral annular configuration. For example, the optical member 52 is provided along the outer edge of the first semiconductor layer 10 when projected onto the X-Y plane. In the example, the optical layer 50 has an opening 54. For example, the opening 54 exposes a portion of a layer under the opening 54. The configuration of the optical member 52 projected onto the X-Y plane is not limited to the quadrilateral annular configuration and may be any configuration extending in a direction parallel to the X-Y plane. For example, the optical layer 50 may include multiple openings 54.

The optical member 52 has a side surface 52s crossing the X-Y plane. The side surface 52s has, for example, at least a component extending in the Z-axis direction. The optical member 52 has a pair of side surfaces 52s. The optical member 52 has, for example, an inner side surface IS and an outer surface OS. The inner side surface IS is the side surface 52s that opposes the region around which the optical member 52 having the frame-like configuration is provided. The outer surface OS is the side surface 52s that faces outside the optical member 52. The pair of side surfaces 52s of the optical member 52 are tilted with respect to the Z-axis direction. An angle θ between the side surface 52s and the X-Y plane is, for example, not less than 30° and not more than 70°. The angle θ between the inner side surface IS and the X-Y plane is, for example, not less than 30° and not more than 70°. The angle θ between the outer surface OS and the X-Y plane is, for example, not less than 30° and not more than 70°.

Thus, by the side surface 52s being tilted with respect to the Z-axis direction, for example, the light distribution angle of the semiconductor light emitting device 110 can be controlled. For example, the side surface 52s may be substantially parallel to the Z-axis direction. Only one selected from the inner side surface IS and the outer surface OS may be tilted with respect to the Z-axis direction.

In the example, the stacked body SB further includes an intermediate layer 40. For example, the intermediate layer 40 is provided between the first semiconductor layer 10 and the optical layer 50. In the example, the optical layer 50 is provided on the intermediate layer 40. For example, the opening 54 exposes a portion of the intermediate layer 40. The intermediate layer 40 includes a nitride semiconductor. For example, the concentration of the impurity included in the intermediate layer 40 is lower than the concentration of the impurity included in the first semiconductor layer 10. For example, the concentration of the impurity included in the intermediate layer 40 is lower than the concentration of the impurity included in the second semiconductor layer 20. The intermediate layer 40 includes, for example, a non-doped GaN layer.

The intermediate layer 40 has a surface 40a facing the side opposite to the light emitting layer 30. In the semiconductor light emitting device 110, the surface 40a is used as a light extraction surface LF. The intermediate layer 40 may be provided if necessary and is omissible. The stacked body SB may further include other layers. For example, the light extraction surface LF is the surface of the stacked body SB that faces the direction from the stacked body SB toward the optical layer 50. For example, the light extraction surface LF crosses the Z-axis direction. For example, the light extraction surface LF is positioned at the outermost side of the stacked body SB and is a surface that has a portion that does not oppose a member that is light-reflective. For example, in the case where the intermediate layer 40 is not included, the surface of the first semiconductor layer 10 is used as the light extraction surface LF. For example, in the case where another layer is further included between the intermediate layer 40 and the optical layer 50, the surface of the other layer is used as the light extraction surface LF.

For example, the semiconductor light emitting device 110 further includes a substrate 4, a first electrode 11, a second electrode 12, and a third electrode 13.

The substrate 4 is stacked with the stacked body SB in the Z-axis direction. The stacked body SB is provided between the substrate 4 and the optical layer 50. In other words, the stacked body SB is provided on the substrate 4; and the optical layer 50 is provided on the stacked body SB. For example, the substrate 4 supports the stacked body SB. The substrate 4 includes, for example, silicon. For example, the substrate 4 is a silicon substrate. For example, the substrate 4 is conductive. In the example, the substrate 4 is electrically connected to the second semiconductor layer 20.

The first electrode 11 is electrically connected to the first semiconductor layer 10. In the example, the first semiconductor layer 10 is provided between the light emitting layer 30 and the first electrode 11. In other words, in the example, the first electrode 11 is provided on the first semiconductor layer 10. An opening 40b is provided in the intermediate layer 40. The opening 40b exposes a portion of the first electrode 11. The first electrode 11 is provided on a portion of the first semiconductor layer 10 exposed at the opening 40b. For example, the first electrode 11 contacts the first semiconductor layer 10. Thereby, the first electrode 11 is electrically connected to the first semiconductor layer 10.

The first electrode 11 has, for example, a frame-like configuration. For example, the first electrode 11 does not overlap a portion of the light emitting layer 30 when projected onto the X-Y plane. Thereby, the light emitted from the light emitting layer 30 is emitted to the outside via the opening of the first electrode 11. For example, the first electrode 11 is disposed at a position not overlapping the optical layer 50 when projected onto the X-Y plane. The first electrode 11 has, for example, a frame-like configuration along the inner side of the optical member 52.

The first electrode 11 is, for example, reflective to the light emitted from the light emitting layer 30. The first electrode 11 includes, for example, at least one selected from Ti, Pt, Al, Ag, Ni, Au, and Ta. The first electrode 11 may include, for example, an alloy including at least one selected from Ti, Pt, Al, Ag, Ni, Au, and Ta. It is more desirable for the first electrode 11 to include at least one selected from Al and Ag. Thereby, for example, the light extraction efficiency can be increased by the first electrode 11 having a high reflectivity to the light emitted from the light emitting layer 30. The thickness of the first electrode 11 is, for example, not less than 10 nm and not more than 10 μm.

A pad portion 11p is provided in the first electrode 11. The pad portion 11p is used, for example, when providing an interconnect between the first electrode 11 and an external member. The pad portion 11p includes, for example, a metal of at least one selected from Ti, Pt, and Au or an alloy including at least one of the metals.

The second electrode 12 is provided, for example, between the second semiconductor layer 20 and the substrate 4. The second electrode 12 is electrically connected to the second semiconductor layer 20 and the substrate 4. For example, the substrate 4 is electrically connected to the second semiconductor layer 20 via the second electrode 12. For example, the second electrode 12 is reflective to the light emitted from the light emitting layer 30. The second electrode 12 includes, for example, Ag. The second electrode 12 includes, for example, Ag or Ag alloy. Thereby, for example, the second electrode 12 has a high reflectivity. The thickness of the second electrode 12 is, for example, not less than 10 nm and not more than 10 μm.

For example, the third electrode 13 is stacked with the substrate 4 in the Z-axis direction. The substrate 4 is provided, for example, between the second electrode 12 and the third electrode 13. For example, the third electrode 13 is electrically connected to the substrate 4. For example, the third electrode 13 is electrically connected to the second semiconductor layer 20 via the substrate 4 and the second electrode 12. The third electrode 13 is used as, for example, an electrical connection with an external member.

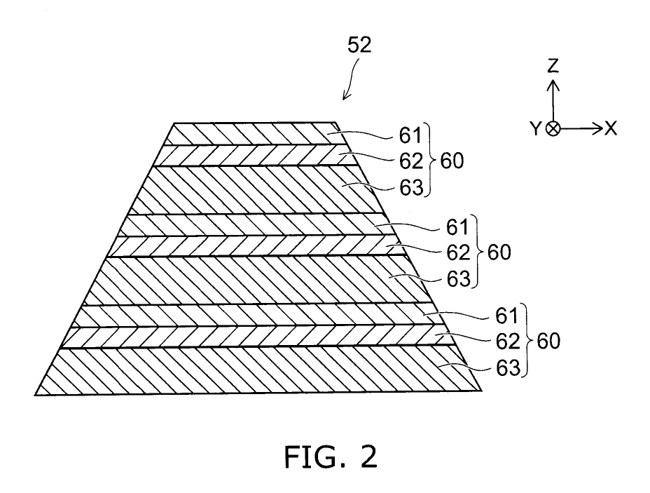

FIG. 2 is a schematic cross-sectional view showing a portion of the semiconductor light emitting device according to the first embodiment.

FIG. 2 is a schematic cross-sectional view showing the optical layer 50.

As shown in FIG. 2, the optical member 52 of the optical layer 50 includes a multilayered film 60. The multilayered film 60 includes a first layer 61, a second layer 62, and a third layer 63. The first layer 61 is separated from the stacked body SB in the Z-axis direction. The second layer 62 is provided between the first layer 61 and the stacked body SB. The third layer 63 is provided between the second layer 62 and the stacked body SB. In other words, the first layer 61 is provided on the second layer 62. The second layer 62 is provided on the third layer 63.

The first to third layers 61 to 63 include, for example, a nitride semiconductor. The first layer 61 and the second layer 62 include Al. The third layer 63 may include Al or may substantially not include Al. The Al composition ratio of the first layer 61 is higher than the Al composition ratio of the second layer 62. The Al composition ratio of the second layer 62 is higher than the Al composition ratio of the third layer 63.

The first layer 61 includes, for example, an AlN layer. The second layer 62 includes, for example, an AlGaN layer. The third layer 63 includes, for example, a GaN layer. The first layer 61 may be, for example, an AlGaN layer having an Al composition ratio that is higher than that of the second layer 62. The third layer 63 may be, for example, an AlGaN layer having an Al composition ratio that is lower than that of the second layer 62.

Thus, at least a portion of the optical member 52 includes Al. In the semiconductor light emitting device 110, for example, the first layer 61 and the second layer 62 include Al. For example, the Al composition ratio of at least a portion of the optical member 52 is higher than the Al composition ratio of the stacked body SB. For example, the Al composition ratio of the at least a portion of the optical member 52 is higher than the Al composition ratio of the first semiconductor layer 10. For example, the Al composition ratio of the at least a portion of the optical member 52 is higher than the Al composition ratio of the second semiconductor layer 20.

As described above, the first semiconductor layer 10, the second semiconductor layer 20, and the light emitting layer 30 include, for example, GaN layers. For example, the first semiconductor layer 10, the second semiconductor layer 20, and the light emitting layer 30 substantially do not include Al. Accordingly, for example, the Al composition ratio of the first layer 61 which is the AlN layer and the Al composition ratio of the second layer 62 which is the AlGaN layer are higher than the Al composition ratios of the first semiconductor layer 10, the second semiconductor layer 20, and the light emitting layers 30.

The optical member 52 includes, for example, multiple multilayered films 60. Each of the multiple multilayered films 60 is stacked in the Z-axis direction. In other words, in the optical member 52, for example, the multiple first layers 61, the multiple second layers 62, and the multiple third layers 63 are repeatedly stacked in the Z-axis direction in the order of the third layer 63, the second layer 62, and the first layer 61.

In the example, the optical member 52 includes three multilayered films 60. The number of the multilayered films 60 included in the optical member 52 is not limited to three and may be one, two, four, or more. The number of layers included in the multilayered film 60 is not limited to three and may be two, four, or more. It is sufficient for the multilayered film 60 to include at least one layer including Al. However, it is favorable for the multilayered film 60 to include multiple layers having different Al composition ratios and for the Al composition ratios to change in stages. The optical member 52 may have, for example, a single-layer structure of an AlN layer, an AlGaN layer, etc.

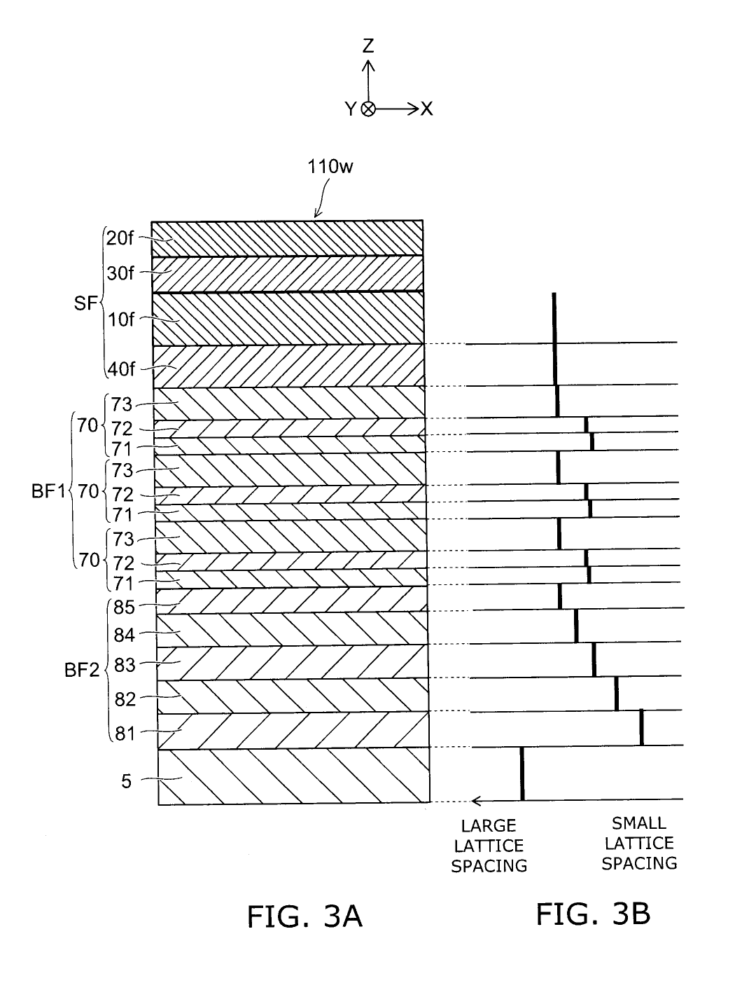

FIG. 3A and FIG. 3B are schematic views showing the workpiece according to the first embodiment.

FIG. 3A is a schematic cross-sectional view showing a workpiece 110w used to manufacture the semiconductor light emitting device 110. The semiconductor light emitting device 110 is manufactured by patterning the workpiece 110w. FIG. 3B is a schematic view showing the lattice spacing of the multiple layers included in the workpiece 110w. In FIG. 3B, the lattice spacing of the corresponding layer increases toward the left side of the page surface.

As shown in FIG. 3A, the workpiece 110w includes, for example, a growth substrate 5, a stacked film SF, a first buffer unit BF1, and a second buffer unit BF2.

The growth substrate 5 includes, for example, silicon. The growth substrate 5 is, for example, a silicon substrate (a silicon wafer). The growth substrate 5 may be, for example, a sapphire substrate, etc.

The stacked film SF is stacked with the growth substrate 5 in the Z-axis direction. The stacked film SF is provided on the growth substrate 5. The stacked film SF includes a first semiconductor film 10f of the first conductivity type used to form the first semiconductor layer 10, a second semiconductor film 20f of the second conductivity type used to form the second semiconductor layer 20, a light emitting film 30f used to form the light emitting layer 30, and an intermediate film 40f used to form the intermediate layer 40.

In the workpiece 110w, the second semiconductor film 20f is separated from the first semiconductor film 10f in the stacking direction (the Z-axis direction) of the growth substrate 5 and the stacked film SF. The light emitting film 30f is provided between the first semiconductor film 10f and the second semiconductor film 20f. In the example, the first semiconductor film 10f is provided between the light emitting film 30f and the intermediate film 40f. In the example, the first semiconductor film 10f is provided on the intermediate film 40f; the light emitting film 30f is provided on the first semiconductor film 10f; and the second semiconductor film 20f is provided on the light emitting film 30f.

The first buffer unit BF1 is provided between the growth substrate 5 and the stacked film SF. The first buffer unit BF1 includes, for example, a multilayered film 70. The multilayered film 70 includes, for example, a first film 71, a second film 72, and a third film 73. The second film 72 is provided, for example, between the first film 71 and the stacked film SF. The third film 73 is provided, for example, between the second film 72 and the stacked film SF. In other words, the second film 72 is provided on the first film 71; and the third film 73 is provided on the second film 72.

The first film 71 includes, for example, an AlN layer. The thickness (the length in the Z-axis direction) of the first film 71 is, for example, 12 nm. The thickness of the first film 71 is, for example, not less than 5 nm and not more than 20 nm.

The second film 72 includes, for example, an AlGaN layer. The thickness of the second film 72 is, for example, 20 nm. The thickness of the second film 72 is, for example, not less than 10 nm and not more than 30 nm. The Al composition ratio of the second film 72 is, for example, 50%. The Al composition ratio of the second film 72 is, for example, not less than 40% and not more than 60%.

The third film 73 includes, for example, a GaN layer. The thickness of the third film 73 is, for example, 500 nm. The thickness of the third film 73 is, for example, not less than 400 nm and not more than 600 nm.

The first buffer unit BF1 includes multiple multilayered films 70. Each of the multiple multilayered films 70 is stacked in the Z-axis direction. In other words, in the first buffer unit BF1, for example, multiple first films 71, multiple second films 72, and multiple third films 73 are repeatedly stacked in the Z-axis direction in this order. In the example, the first buffer unit BF1 includes three multilayered films 70. The number of the multilayered films 70 included in the first buffer unit BF1 may be one, two, four, or more. Also, the number of films included in the multilayered film 70 is not limited to three and may be any number not less than two.

Thus, at least a portion of the first buffer unit BF1 includes Al. In the example, the first film 71 and the second film 72 include Al. The composition ratio of at least a portion of the first buffer unit BF1 is higher than the Al composition ratio of the stacked film SF.

The optical layer 50 is formed by patterning the first buffer unit BF1. In other words, the multilayered film 70 is used to form the multilayered film 60. The first film 71 is used to form the first layer 61. The second film 72 is used to form the second layer 62. The third film 73 is used to form the third layer 63.

The second buffer unit BF2 is provided between the growth substrate 5 and the first buffer unit BF1. The second buffer unit BF2 includes, for example, a first buffer film 81, a second buffer film 82, a third buffer film 83, a fourth buffer film 84, and a fifth buffer film 85. The number of buffer films included in the second buffer unit BF2 is not limited to five and may be one to four, six, or more.

The second buffer film 82 is provided between the first buffer film 81 and the first buffer unit BF1. The third buffer film 83 is provided between the second buffer film 82 and the first buffer unit BF1. The fourth buffer film 84 is provided between the third buffer film 83 and the first buffer unit BF1.

The fifth buffer film 85 is provided between the fourth buffer film 84 and the first buffer unit BF1. In other words, the second buffer film 82 is provided on the first buffer film 81; the third buffer film 83 is provided on the second buffer film 82; the fourth buffer film 84 is provided on the third buffer film 83; and the fifth buffer film 85 is provided on the fourth buffer film 84.

The first buffer film 81 includes, for example, an AlN layer. The thickness of the first buffer film 81 is, for example, 120 nm. The thickness of the first buffer film 81 is, for example, not less than 50 nm and not more than 200 nm.

The second buffer film 82 includes, for example, an AlGaN layer. The thickness of the second buffer film 82 is, for example, 100 nm. The thickness of the second buffer film 82 is, for example, not less than 50 nm and not more than 200 nm. The Al composition ratio of the second buffer film 82 is lower than the Al composition ratio of the first buffer film 81. The Al composition ratio of the second buffer film 82 is, for example, 50%. The Al composition ratio of the second buffer film 82 is, for example, not less than 40% and not more than 60%.

The third buffer film 83 includes, for example, an AlGaN layer. The thickness of the third buffer film 83 is, for example, 200 nm. The thickness of the third buffer film 83 is, for example, not less than 100 nm and not more than 300 nm. The Al composition ratio of the third buffer film 83 is lower than the Al composition ratio of the second buffer film 82. The Al composition ratio of the third buffer film 83 is, for example, 30%. The Al composition ratio of the third buffer film 83 is, for example, not less than 20% and not more than 40%.

The fourth buffer film 84 includes, for example, an AlGaN layer. The thickness of the fourth buffer film 84 is, for example, 250 nm. The thickness of the fourth buffer film 84 is, for example, not less than 150 nm and not more than 350 nm. The Al composition ratio of the fourth buffer film 84 is lower than the Al composition ratio of the third buffer film 83. The Al composition ratio of the fourth buffer film 84 is, for example, 15%. The Al composition ratio of the fourth buffer film 84 is, for example, not less than 5% and not more than 25%.

The fifth buffer film 85 includes, for example, a GaN layer. The thickness of the fifth buffer film 85 is, for example, 400 nm. The thickness of the fifth buffer film 85 is, for example, not less than 300 nm and not more than 500 nm. The Al composition ratio of the fifth buffer film 85 is lower than the Al composition ratio of the fourth buffer film 84.

As shown in FIG. 3B, for example, due to the first buffer unit BF1 and the second buffer unit BF2, the difference of the lattice spacing between the growth substrate 5 including silicon and the first semiconductor film 10f including GaN changes in stages. For example, by stacking multiple layers having different Al composition ratios, the difference of the lattice spacing between adjacent layers is reduced. Thereby, the stress is stored without relaxation occurring by, for example, gradually changing the lattice spacing in the first buffer unit BF1 and the second buffer unit BF2. The first buffer unit BF1 and the second buffer unit BF2 suppress, for example, the warp of the stacked film SF caused by stress that is stored. The first buffer unit BF1 and the second buffer unit BF2 are, for example, stress control layers for controlling the stress stored in the stacked film SF.

There is a semiconductor light emitting device in which the first buffer unit BF1 and the second buffer unit BF2 are removed in a manufacturing process. After removing the first buffer unit BF1 and the second buffer unit BF2 in such a semiconductor light emitting device, there are cases where the balance of the stress degrades and warp and/or cracks undesirably occur in the stacked film SF and the stacked body SB formed from the stacked film SF. The warp and/or cracks of the stacked body SB cause, for example, the yield of the semiconductor light emitting device to decrease.

For example, to suppress the warp and cracks of the stacked body SB, it also may be considered to leave the stress control layer as-is on the stacked body SB. However, in such a case, for example, a portion of the light emitted from the light emitting layer 30 is absorbed by the stress control layer; and the light extraction efficiency undesirably decreases.

Conversely, in the semiconductor light emitting device 110 according to the embodiment, the optical layer 50 including the optical member 52 is provided. The optical layer 50 is formed from, for example, the first buffer unit BF1 by patterning the first buffer unit BF1. Thereby, in the semiconductor light emitting device 110, for example, the degradation of the balance of the stress can be suppressed. In other words, in the semiconductor light emitting device 110, for example, the occurrence of warp and cracks in the stacked body SB can be suppressed.

The optical layer 50 has the opening 54 and transmits the light emitted from the light emitting layer 30 via the opening 54. Thereby, in the semiconductor light emitting device 110, the absorption of the light emitted from the light emitting layer 30 by the optical layer 50 can be suppressed. In other words, in the semiconductor light emitting device 110, the decrease of the light extraction efficiency can be suppressed.

Thus, in the semiconductor light emitting device 110, warp and cracks can be suppressed while suppressing the decrease of the light extraction efficiency.

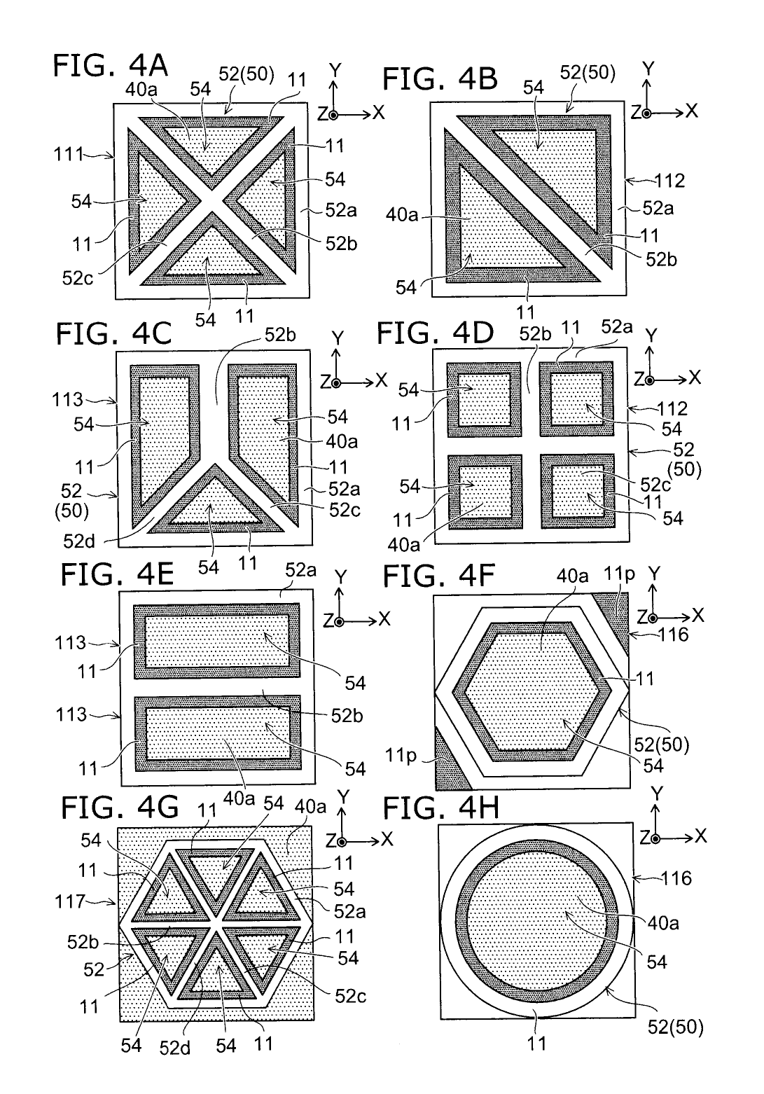

FIG. 4A to FIG. 4H are schematic plan views showing other semiconductor light emitting devices according to the first embodiment.

In a semiconductor light emitting device 111 as shown in FIG. 4A, the optical member 52 of the optical layer 50 includes a first portion 52a, a second portion 52b, and a third portion 52c. The first portion 52a has a frame-like configuration. The first portion 52a is provided along, for example, the outer edge of the stacked body SB. The configuration of the first portion 52a projected onto the X-Y plane is a quadrilateral annular configuration. The second portion 52b and the third portion 52c partition the region inside the first portion 52a. The second portion 52b extends along, for example, one diagonal of the first portion 52a. The third portion 52c extends along, for example, the other diagonal of the first portion 52a. In other words, in the example, the configuration of the second portion 52b and the third portion 52c projected onto the X-Y plane is an X-shaped configuration. Thus, the configuration of the optical member 52 projected onto the X-Y plane may be, for example, a configuration in which the interior of a frame having a quadrilateral configuration is partitioned by an X-shaped configuration.

In the example, the optical layer 50 has four openings 54. Also, in the example, the first electrode 11 has four portions. The four portions of the first electrode 11 have frame-like configurations along the inner side of the optical member 52 to respectively overlap the four openings 54 when projected onto the X-Y plane. The four portions of the first electrode 11 are electrically connected by a not-shown interconnect portion. For example, the interconnect portion may pass over the optical layer 50 and may pass under the optical layer 50.

Thus, in the case where the optical layer 50 has the multiple openings 54, the first electrode 11 is disposed at portions overlapping each of the multiple openings 54. Thereby, for example, the fluctuation of the voltage applied to the first semiconductor layer 10 in directions parallel to the X-Y plane can be suppressed. For example, it is unnecessary for the first electrode 11 to always have a portion corresponding to each of the multiple openings 54.

In a semiconductor light emitting device 112 as shown in FIG. 4B, the optical member 52 includes the first portion 52a and the second portion 52b. Thus, the configuration of the optical member 52 projected onto the X-Y plane may be, for example, a configuration in which the interior of a frame having a quadrilateral configuration is partitioned along the diagonal.

In a semiconductor light emitting device 113 as shown in FIG. 4C, the optical member 52 includes the first portion 52a, the second portion 52b, the third portion 52c, and a fourth portion 52d. The first portion 52a has, for example, a quadrilateral annular configuration. The second portion 52b, the third portion 52c, and the fourth portion 52d partition the region inside the first portion 52a. The second portion 52b extends, for example, from the vicinity of the center of one side of the first portion 52a toward the center of the first portion 52a. The third portion 52c extends, for example, from one apex portion of the first portion 52a toward the center of the first portion 52a. The fourth portion 52d extends, for example, from one other apex portion of the first portion 52a toward the center of the first portion 52a. In other words, in the example, the configuration of the second portion 52b, the third portion 52c, and the fourth portion 52d projected onto the X-Y plane is a Y-shaped configuration. Thus, the configuration of the optical member 52 projected onto the X-Y plane may be, for example, a configuration in which the interior of a frame having a quadrilateral configuration is partitioned by a Y-shaped configuration.

In a semiconductor light emitting device 114 as shown in FIG. 4D, the optical member 52 includes the first portion 52a, the second portion 52b, and the third portion 52c. The first portion 52a has, for example, a quadrilateral annular configuration. The second portion 52b and the third portion 52c partition the region inside the first portion 52a. The second portion 52b extends, for example, in a direction parallel to one side of the first portion 52a. The third portion 52c extends, for example, in a direction parallel to one other side crossing the one side of the first portion 52a. The third portion 52c is, for example, orthogonal to the second portion 52b. In other words, in the example, the configuration of the second portion 52b and the third portion 52c projected onto the X-Y plane is a cross-shaped configuration. Thus, the configuration of the optical member 52 projected onto the X-Y plane may be, for example, a configuration in which the interior of a frame having a quadrilateral configuration is partitioned by a cross-shaped configuration.

In a semiconductor light emitting device 115 as shown in FIG. 4E, the optical member 52 includes the first portion 52a and the second portion 52b. The first portion 52a has, for example, a quadrilateral annular configuration. The second portion 52b extends, for example, in a direction parallel to one side of the first portion 52a. Thus, the configuration of the optical member 52 projected onto the X-Y plane may be, for example, a configuration in which the interior of a frame having a quadrilateral configuration is partitioned parallel to one side of the frame.

In a semiconductor light emitting device 116 as shown in FIG. 4F, the configuration of the optical member 52 projected onto the X-Y plane has a hexagonal frame-like configuration. Thus, the configuration of the optical member 52 having the frame-like configuration is not limited to a quadrilateral configuration and may be another polygonal configuration.

Also, in the semiconductor light emitting device 116, the pad portion 11p is disposed outside the optical member 52 having the frame-like configuration. The pad portion 11p is disposed, for example, outside the optical member 52 on the surface 40a (the light extraction surface LF) of the intermediate layer 40. Thus, the pad portion 11p may be disposed outside the optical member 52. In such a case, the pad portion 11p is, for example, electrically connected to the first electrode 11 via a not-shown interconnect. The interconnect may pass over the optical layer 50 and may pass under the optical layer 50.

In a semiconductor light emitting device 117 as shown in FIG. 4G, the optical member 52 includes the first portion 52a, the second portion 52b, the third portion 52c, and the fourth portion 52d. The first portion 52a has, for example, an annular configuration having a hexagonal configuration. The second portion 52b, the third portion 52c, and the fourth portion 52d partition the region inside the first portion 52a. The second portion 52b extends, for example, along one diagonal passing through the center of the first portion 52a. The third portion 52c extends, for example, along one other diagonal passing through the center of the first portion 52a. The fourth portion 52d extends, for example, along another diagonal passing through the center of the first portion 52a. Thus, the configuration of the optical member 52 projected onto the X-Y plane may be, for example, a configuration in which the interior of a frame having a hexagonal configuration is partitioned along each of the diagonals passing through the center.

In a semiconductor light emitting device 118 as shown in FIG. 4H, the configuration of the optical member 52 projected onto the X-Y plane is a substantially circular frame-like configuration. The configuration of the optical member 52 projected onto the X-Y plane is a circular ring configuration. Thus, the configuration of the optical member 52 having the frame-like configuration is not limited to a quadrilateral configuration and may be circular, elliptical, etc.

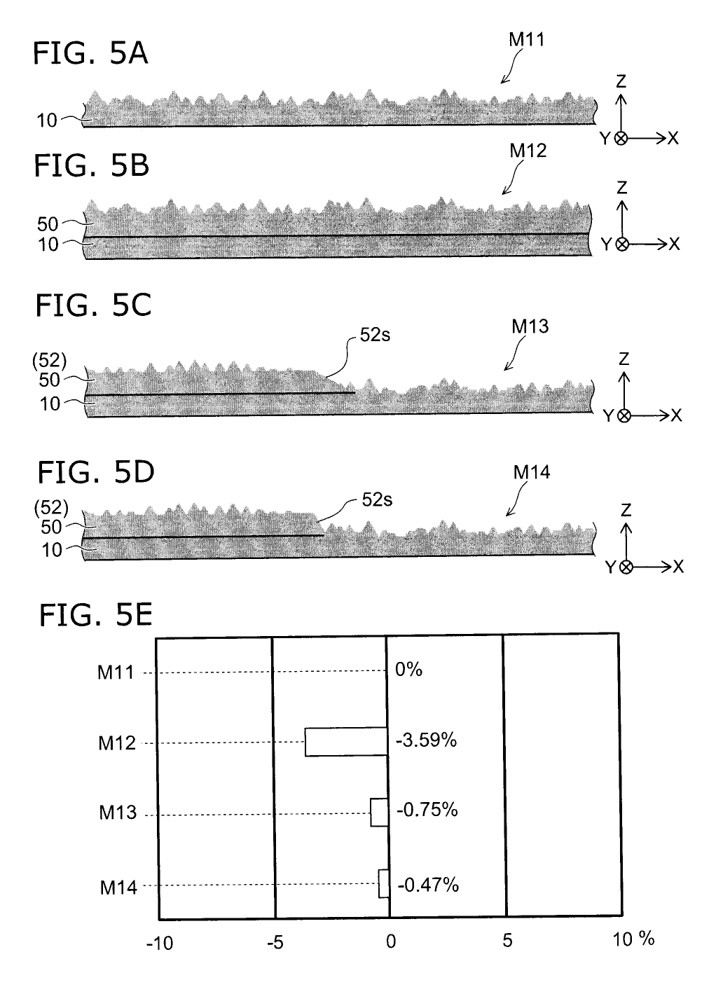

FIG. 5A to FIG. 5E are schematic views showing the results of optical simulations of the semiconductor light emitting device according to the first embodiment.

FIG. 5A to FIG. 5D are schematic cross-sectional views showing models M11 to M14 used in the optical simulations.

FIG. 5E is a graph showing examples of the results of the optical simulations.

As shown in FIG. 5A, the optical layer 50 is not provided in the model M11. In other words, the model M11 is a model in which the first buffer unit BF1 and the second buffer unit BF2, which are the stress control layers in the manufacturing processes, are removed.

In the model M12 as shown in FIG. 5B, the optical layer 50 covers the entire first semiconductor layer 10. The optical member 52 is not provided in the model M12. In other words, the model M12 is a model in which the first buffer unit BF1 remains as-is.

In the model M13 and the model M14 as shown in FIG. 5C and FIG. 5D, the optical layer 50 includes the optical member 52. In other words, the model M13 and the model M14 are models of the semiconductor light emitting device according to the embodiment. The value of the angle θ of the side surface 52s is different between the model M13 and the model M14. The angle θ is 30° in the model M13. On the other hand, the angle θ is 60° in the model M14.

The configuration of the stacked body SB projected onto the X-Y plane is a square configuration in each of the models M11 to M14. In the model M13 and the model M14, the configuration of the optical member 52 projected onto the X-Y plane is a quadrilateral annular configuration. In other words, the model M13 and the model M14 are models of the semiconductor light emitting device 110. In the model M13 and the model M14, the surface area of the optical member 52 projected onto the X-Y plane is set to be 20% of the surface area of the stacked body SB projected onto the X-Y plane. However, the calculation of the surface area of the optical member 52 is performed using the surface area of the upper surface portion not including the side surface 52s. Accordingly, strictly speaking, the surface area of the optical member 52 of the model M13 which has a small angle θ is slightly greater than the surface area of the optical member 52 of the model M14.

FIG. 5E shows the calculation results of the light extraction efficiency of each of the models M11 to M14. FIG. 5E shows the change relative to the light extraction efficiency of the model M11 by using the results of the model M11 as a reference.

In the model M12 as shown in FIG. 5E, the light extraction efficiency undesirably decreases about 3.59% with respect to the model M11. Conversely, the light extraction efficiency of the model M13 is about −0.75% with respect to the model M11; and the light extraction efficiency of the model M14 is about −0.47% with respect to the model M11. Thus, in the case where the optical layer 50 including the optical member 52 is provided, the decrease of the light extraction efficiency can be suppressed to be less than 1% of the light extraction efficiency of the case where the optical layer 50 is not provided. Accordingly, in the semiconductor light emitting device 110 according to the embodiment, the decrease of the light extraction efficiency can be suppressed even in the case where the optical layer 50 is provided.

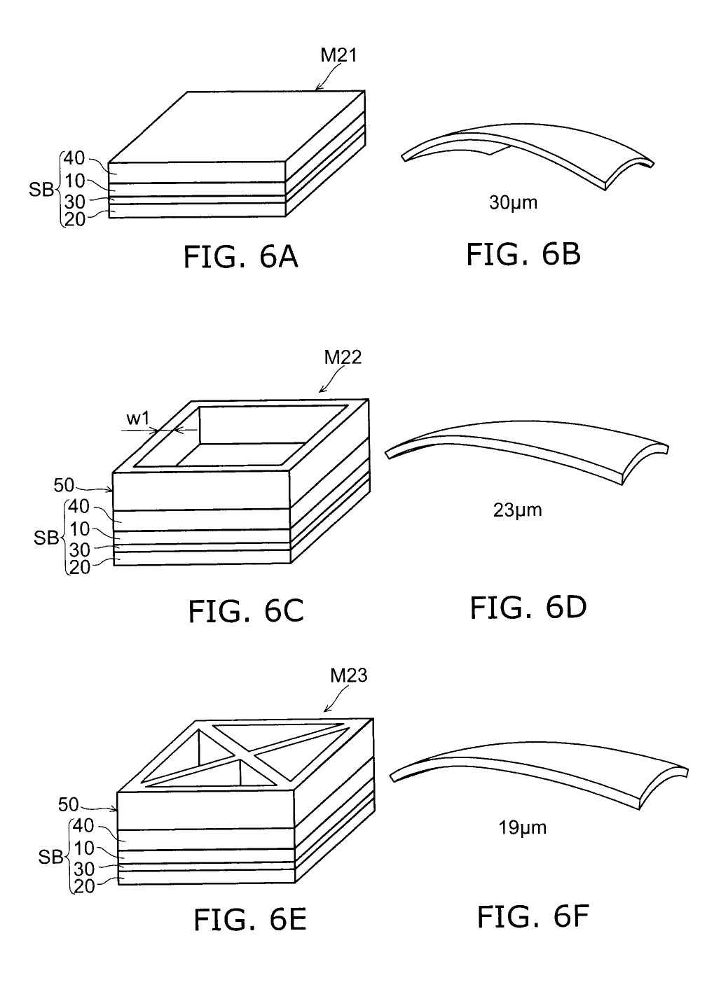

FIG. 6A to FIG. 6F are schematic views showing the results of stress simulations of the semiconductor light emitting device according to the first embodiment.

FIG. 6A is a schematic perspective view showing a model M21 used in the stress simulation.

FIG. 6B schematically shows the results of the stress simulation of the model M21.

FIG. 6C is a schematic perspective view showing a model M22 used in the stress simulation.

FIG. 6D schematically shows the results of the stress simulation of the model M22.

FIG. 6E is a schematic perspective view showing a model M23 used in the stress simulation.

FIG. 6F schematically shows the results of the stress simulation of the model M23.

As shown in FIG. 6A, the optical layer 50 is not provided in the model M21.

In the model M21 as shown in FIG. 6B, the warp amount (the amount of the change of the Z-axis direction) of the stacked body SB is about 30 μm.

In the model M22 as shown in FIG. 6C, the optical layer includes the optical member 52 having a quadrilateral annular configuration. In other words, the model M22 is a model of the semiconductor light emitting device 110.

In the model M22 as shown in FIG. 6D, the warp amount of the stacked body SB is about 23 μm. Thus, the warp of the stacked body SB is about 23% lower for the model M22 than for the model M21. In the model M22, a width w1 of the optical member 52 is set to be 50 μm.

In the model M23 as shown in FIG. 6E, the configuration of the optical member 52 of the optical layer 50 projected onto the X-Y plane is a configuration in which the interior of a frame having a quadrilateral configuration is partitioned by an X-shaped configuration. In other words, the model M23 is a model of the semiconductor light emitting device 111.

In the model M23 as shown in FIG. 6F, the warp amount of the stacked body SB is about 19 μm. Thus, the warp of the stacked body SB is about 37% lower for the model M23 than for the model M21. In the model M23 as well, the width w1 of the optical member 52 is 50 μm.

Thus, compared to the case where the optical layer 50 is not provided, the warp of the stacked body SB can be suppressed in the semiconductor light emitting device 110 according to the embodiment. Also, the warp of the stacked body SB can be suppressed more appropriately in the semiconductor light emitting device 111 according to the embodiment. In other words, the warp of the stacked body SB can be suppressed more appropriately by increasing the surface area of the optical member 52.

There is a trade-off relationship between the improvement of the warp of the stacked body SB and the increase of the light extraction efficiency. In other words, although the warp of the stacked body SB can be suppressed by increasing the surface area of the optical member 52, on the other hand, the light extraction efficiency undesirably decreases. However, although the decrease of the light extraction efficiency can be suppressed by reducing the surface area of the optical member 52, on the other hand, the suppression effect of the warp of the stacked body SB undesirably decreases. Accordingly, the surface area of the optical member 52 projected onto the X-Y plane is set to be, for example, not less than 10% and not more than 65% of the surface area of the stacked body SB projected onto the X-Y plane. Thereby, for example, the decrease of the light extraction efficiency and the warp of the stacked body SB can be appropriately suppressed.

A method for manufacturing the semiconductor light emitting device according to the embodiment will now be described.

The semiconductor light emitting device 110 will now be described as an example. The manufacturing method recited below is not limited to the semiconductor light emitting device 110 and is applicable also to, for example, the semiconductor light emitting devices 111 to 118.

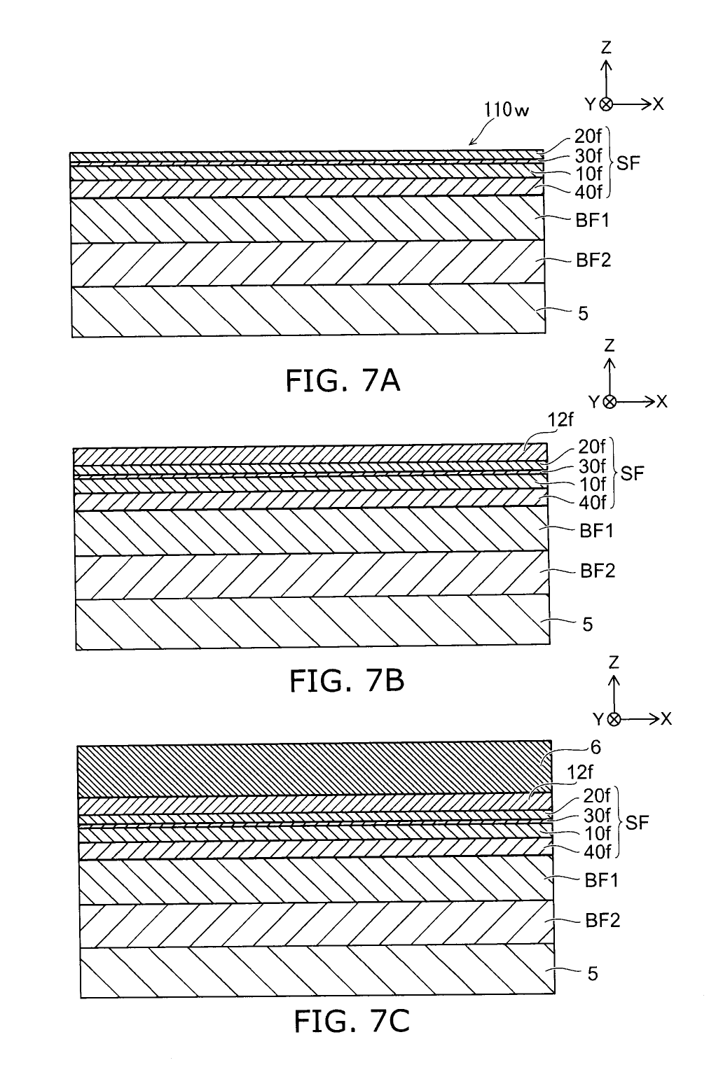

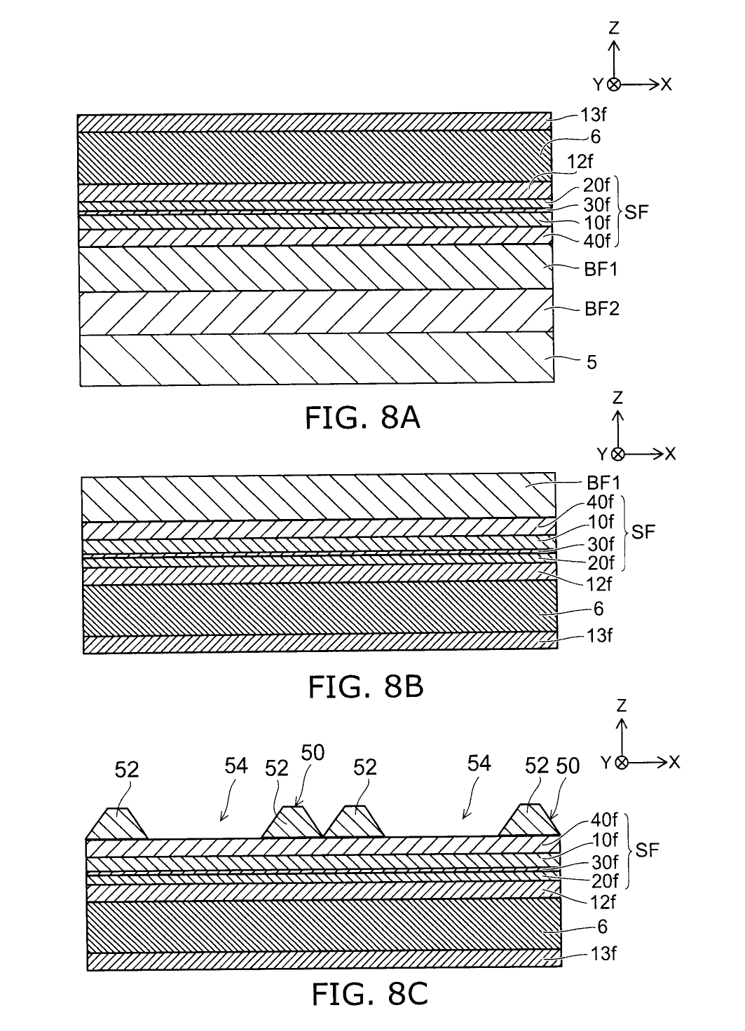

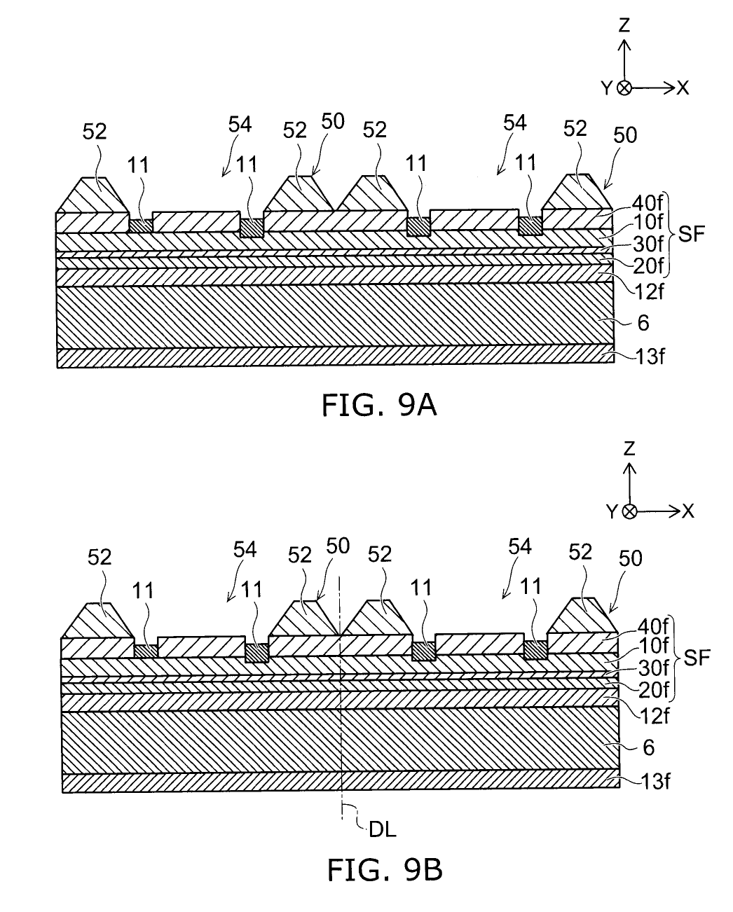

FIG. 7A to FIG. 7C, FIG. 8A to FIG. 8C, FIG. 9A, and FIG. 9B are schematic cross-sectional views showing the method for manufacturing the semiconductor light emitting device according to the first embodiment.

In the manufacture of the semiconductor light emitting device 110 as shown in FIG. 7A, first, the workpiece 110w is prepared. The preparation of the workpiece 110w includes forming the workpiece 110w by, for example, forming the second buffer unit BF2 on the growth substrate 5, forming the first buffer unit BF1 on the second buffer unit BF2, forming the intermediate film 40f on the first buffer unit BF1, forming the first semiconductor film 10f on the intermediate film 40f, forming the light emitting film 30f on the first semiconductor film 10f, and forming the second semiconductor film 20f on the light emitting film 30f.

For convenience in FIG. 7A to FIG. 7C, FIG. 8A, and FIG. 8B, the first buffer unit BF1 and the second buffer unit BF2 are not shown.

As shown in FIG. 7B, a conductive film 12f that is used to form the second electrode 12 is formed on the second semiconductor film 20f by, for example, sputtering, vapor deposition, etc.

As shown in FIG. 7C, a support substrate 6 that is used to form the substrate 4 is adhered to the conductive film 12f. In other words, the support substrate 6 is adhered to the stacked film SF. The support substrate 6 includes, for example, silicon. The support substrate 6 is, for example, a silicon substrate. For example, Au/Sn solder or the like is used to adhere the support substrate 6.

As shown in FIG. 8A, a conductive film 13f that is used to form the third electrode 13 is formed on the support substrate 6 by, for example, sputtering, vapor deposition, etc.

As shown in FIG. 8B, the growth substrate 5 and the second buffer unit BF2 are removed by, for example, at least one selected from polishing and etching.

As shown in FIG. 8C, a portion of the first buffer unit BF1 is removed by, for example, photolithography and etching. Thereby, the multiple optical layers 50 are formed from the first buffer unit BF1. In each of the multiple optical layers 50, the optical member 52 is formed in, for example, a quadrilateral annular configuration.

At this time, the optical member 52 extends in a direction perpendicular to the stacking direction (the Z-axis direction) of the growth substrate 5 and the stacked film SF. The length of the optical member 52 in the Z-axis direction is longer than the length of the first semiconductor film 10f in the Z-axis direction. The surface area of the optical member 52 projected onto the X-Y plane is less than the surface area of the stacked film SF projected onto the X-Y plane. The surface area of the optical member 52 projected onto the X-Y plane is less than, for example, the surface area of the first semiconductor film 10f projected onto the X-Y plane.

For example, dry etching is used to form the optical layer 50. The etching gas of the dry etching includes, for example, at least one selected from Cl₂ gas, Ar gas, and a gas mixture of Cl₂ gas and Ar gas. Thereby, for example, the optical layer 50 can be formed with high precision.

As shown in FIG. 9A, the multiple first electrodes 11 are formed by, for example, photolithography, etching, vapor deposition, sputtering, etc. For example, the multiple first electrodes 11 are disposed respectively in the regions inside the optical members 52 of the multiple optical layers 50.

As shown in FIG. 9B, the workpiece 110w is cut along, for example, a dicing line DL set between the multiple optical layers 50 to be singulated into the multiple optical layers 50. Thereby, the semiconductor light emitting device 110 according to the embodiment is completed.

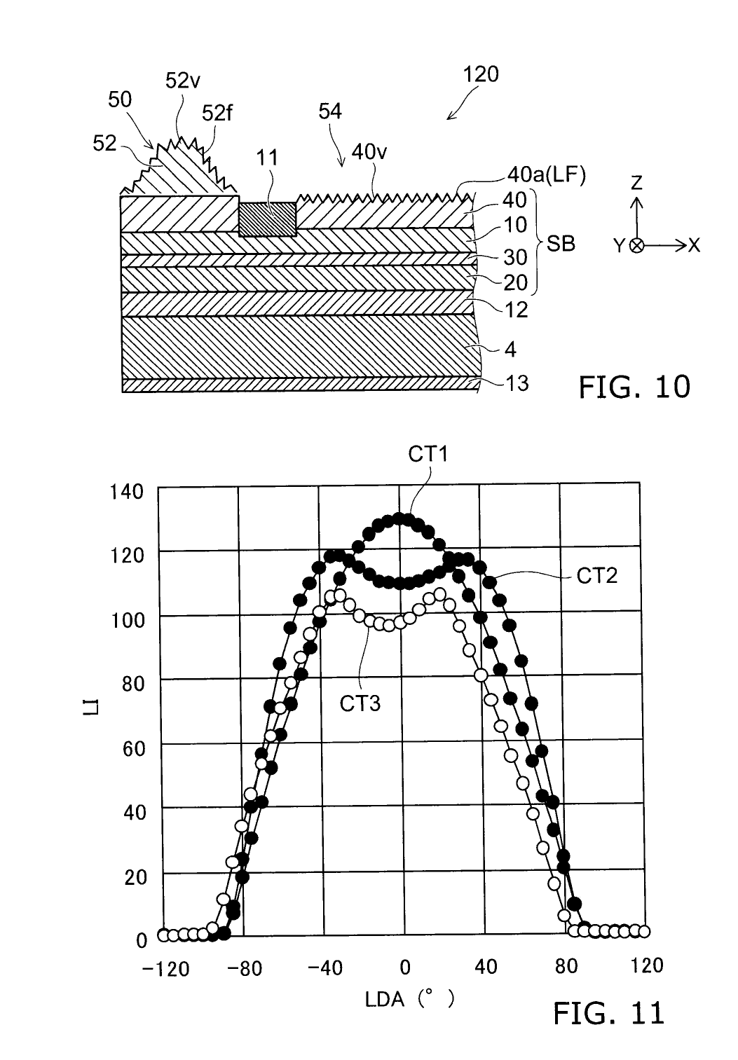

FIG. 10 is a schematic plan view showing another semiconductor light emitting device according to the first embodiment.

In the semiconductor light emitting device 120 as shown in FIG. 10, an unevenness 52v is provided in a surface 52f of the optical member 52. In other words, the surface 52f of the optical member 52 is surface-roughened in the semiconductor light emitting device 120. The surface 52f is, for example, the entire surface of the optical member 52 facing the side opposite to the stacked body SB. The surface 52f includes, for example, the side surface 52s. The unevenness 52v is larger than, for example, the wavelength of the light emitted from the light emitting layer 30. The distance between the apex portion and the bottom portion of the unevenness 52v (the height of the unevenness 52v) is, for example, not less than 400 nm and not more than 1500 nm.

Also, in the semiconductor light emitting device 120, an unevenness 40v is provided in the surface 40a of the intermediate layer 40. In other words, the unevenness 40v is provided in the light extraction surface LF of the stacked body SB. In other words, the light extraction surface LF is surface-roughened. The unevenness 40v is larger than, for example, the wavelength of the light emitted from the light emitting layer 30. The distance between the apex portion and the bottom portion of the unevenness 40v (the height of the unevenness 40v) is, for example, not less than 400 nm and not more than 1500 nm.

Thus, by providing the unevenness 52v and the unevenness 40v, for example, total internal reflections at the surface 52f and the surface 40a of the light emitted from the light emitting layer 30 can be suppressed. Thereby, for example, the light extraction efficiency can be increased further.

In the manufacture of the semiconductor light emitting device 120, first, the multiple optical layers 50 are formed from the first buffer unit BF1 by a method that is similar to the case of the semiconductor light emitting device 110 (referring to FIG. 8C). Subsequently, etching of the multiple optical layers 50 and the intermediate film 40f is performed. At this time, the portions of the intermediate film 40f of the stacked film SF exposed at each of the multiple openings 54 are used as the light extraction surface LF. The light extraction surface LF is, for example, the surface of the stacked film SF facing the direction from the stacked film SF toward the optical layer 50. Thereby, the unevenness 52v is formed in the surface 52f of the optical member 52 of each of the multiple optical layers 50. Then, the unevenness 40v is formed in the light extraction surface LF of the stacked film SF.

For example, at least one selected from dry etching and wet etching is used to form the unevenness 52v and the unevenness 40v. In the case where the unevenness 52v and the unevenness 40v are formed by dry etching, the etching gas includes, for example, Cl₂ gas. On the other hand, in the case where the unevenness 52v and the unevenness 40v are formed by wet etching, the etchant includes, for example, a KOH (potassium hydroxide) aqueous solution.

FIG. 11 is a graph showing an example of characteristics of the semiconductor light emitting device according to the first embodiment.

FIG. 11 is a graph showing an example of the relationship between the light distribution angle and the light intensity of the semiconductor light emitting device 120.

In FIG. 11, the horizontal axis is a light distribution angle LDA (°) of the light emitted from the light emitting layer 30; and the vertical axis is an intensity LI (arbitrary units (a.u.)) of the light emitted from the light emitting layer 30. In FIG. 11, a characteristic CT1 is an example of a characteristic in the case where the unevenness 52v and the unevenness 40v are formed by wet etching using the KOH aqueous solution. A characteristic CT2 and a characteristic CT3 are examples of characteristics in the case where the unevenness 52v and the unevenness 40v are formed by dry etching using Cl₂ gas. The characteristic CT2 is an example of a characteristic in the case where the unevenness 40v is formed with a higher density in the dry etching than the characteristic CT3. The characteristic CT3 is an example of a characteristic in the case where the unevenness 40v is formed with a lower density in the dry etching than the characteristic CT2.

As shown in FIG. 11, the characteristics of the light distribution angle LDA when the unevenness 52v and the unevenness 40v are formed by dry etching are different from the characteristic of the light distribution angle LDA when the unevenness 52v and the unevenness 40v are formed by wet etching. Thus, for example, the light distribution angle of the semiconductor light emitting device 120 can be controlled by the method for forming the unevenness 52v and the unevenness 40v.

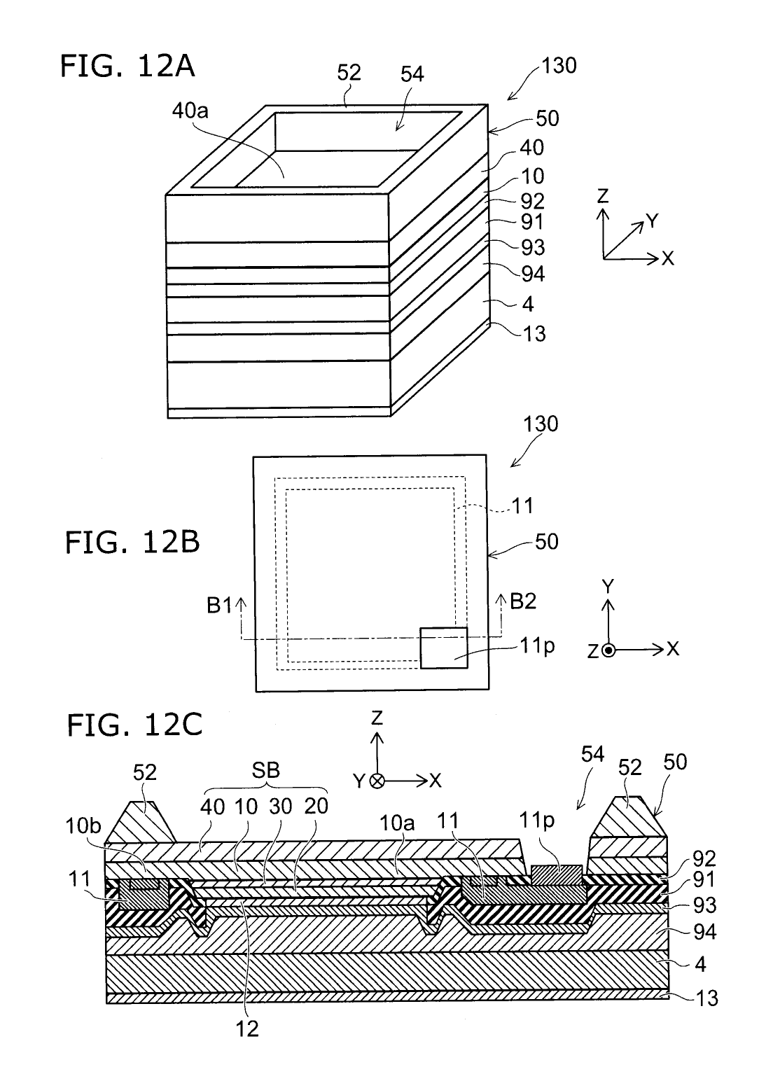

FIG. 12A to FIG. 12C are schematic views showing another semiconductor light emitting device according to the first embodiment.

FIG. 12A is a schematic perspective view; FIG. 12B is a schematic plan view; and FIG. 12C is a schematic cross-sectional view. FIG. 12C shows a cross section along line B1-B2 of FIG. 12B.

As shown in FIG. 12A to FIG. 12C, the semiconductor light emitting device 130 further includes a first insulating layer 91, a second insulating layer 92, a first conductive layer 93, and a second conductive layer 94.

In the semiconductor light emitting device 130, the first semiconductor layer 10 includes a first region 10a that overlaps the second semiconductor layer 20, and a second region 10b that does not overlap the second semiconductor layer 20 when projected onto the X-Y plane. The first insulating layer 91 is provided at least between the second region 10b and the substrate 4. The first electrode 11 is provided between the second region 10b and the first insulating layer 91 and is electrically connected to the first semiconductor layer 10. For example, the first insulating layer 91 electrically insulates the first electrode 11 from the second semiconductor layer 20. For example, the first insulating layer 91 electrically insulates the first electrode 11 from the light emitting layer 30. For example, the first insulating layer 91 suppresses shorts between the first semiconductor layer 10 and the second semiconductor layer 20 due to the first electrode 11. The second insulating layer 92 is provided, for example, between the first insulating layer 91 and the first semiconductor layer 10. The first insulating layer 91 and the second insulating layer 92 include, for example, a silicon oxide film, etc.

In the example, the first electrode 11 has a portion extending in the X-axis direction and a portion extending in the Y-axis direction. In the example, the configuration of the first electrode 11 projected onto the X-Y plane is, for example, a quadrilateral annular configuration. Similarly, the first insulating layer 91 and the second insulating layer 92 have quadrilateral annular configurations. In the example, the first electrode 11 may be disposed at a position overlapping the optical member 52 when projected onto the X-Y plane.

The first conductive layer 93 is provided, for example, between the second electrode 12 and the substrate 4 and between the first insulating layer 91 and the substrate 4. The first conductive layer 93 is electrically connected to the second electrode 12. The second conductive layer 94 is provided, for example, between the first conductive layer 93 and the substrate 4. For example, the second conductive layer 94 is electrically connected to the first conductive layer 93 and the substrate 4. Thereby, the substrate 4 is electrically connected to the second electrode 12 via the first conductive layer 93 and the second conductive layer 94. The first conductive layer 93 and the second conductive layer 94 include, for example, a metal material having a high reflectance such as Ag, Al, etc.

Thus, the first electrode 11 may be provided on the first semiconductor layer 10 and may be provided under the first semiconductor layer 10.

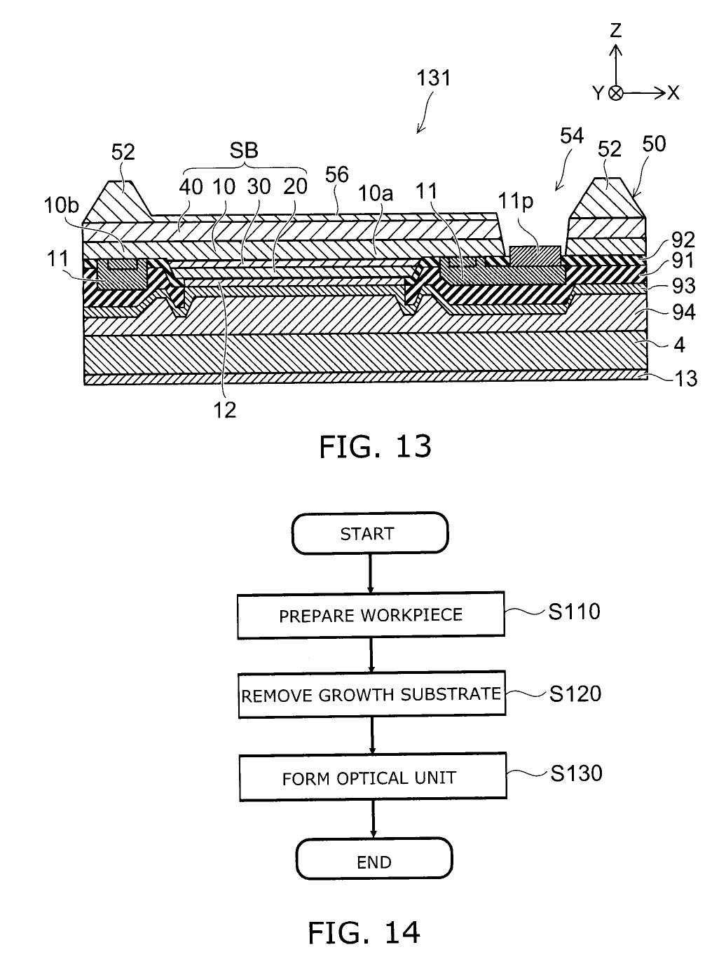

FIG. 13 is a schematic cross-sectional view showing another semiconductor light emitting device according to the first embodiment.

As in the semiconductor light emitting device 131 shown in FIG. 13, in the case where the first electrode 11 is provided under the first semiconductor layer 10, a portion of the optical layer 50 may be provided thinly over the stacked body SB.

In other words, the optical layer 50 may include, for example, the optical member 52 and a thin film portion 56 that is thinner than the optical member 52.

### Second Embodiment

FIG. 14 is a flowchart showing a method for manufacturing a semiconductor light emitting device according to a second embodiment.

As shown in FIG. 14, the method for manufacturing the semiconductor light emitting device according to the embodiment includes step S110 of preparing the workpiece 110w, step S120 of removing the growth substrate 5, and step S130 of forming the optical member 52.

In step S110, for example, the processing described in regard to FIG. 7A is implemented. In step S120, for example, the processing described in regard to FIG. 8B is implemented. In step S130, for example, the processing described in regard to FIG. 8C is implemented. Thereby, for example, the semiconductor light emitting device 110 in which warp and cracks are suppressed while suppressing the decrease of the light extraction efficiency is manufactured.

Step S130 may include, for example, a step of removing a portion of the first buffer unit BF1 by dry etching.

Also, the method for manufacturing the semiconductor light emitting device according to the embodiment may further include, for example, a step of forming the unevenness 52v and the unevenness 40v respectively in the surface 52f of the optical member 52 and the light extraction surfaces LF of the stacked film SF.

According to the embodiment, a semiconductor light emitting device and a method for manufacturing the semiconductor light emitting device are provided in which warp and cracks can be suppressed while suppressing the decrease of the light extraction efficiency.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

In the specification of the application, “perpendicular” and “parallel” refer to not only strictly perpendicular and strictly parallel but also include, for example, the fluctuation due to manufacturing processes, etc.; and it is sufficient to be substantially perpendicular and substantially parallel. In the specification of the application, the state of being provided on a component includes not only the state of being provided in direct contact with the component but also the state of being provided with another component inserted therebetween. The state of being stacked includes not only the state of overlapping in contact with each other but also the state of overlapping with another component inserted therebetween. The state of being opposed includes not only the state of directly facing each other but also the state of facing each other with another component being inserted therebetween. In the specification of the application, being “electrically connected” includes not only being connected in direct contact but also includes being connected via another conductive member, etc.

Hereinabove, embodiments of the invention are described with reference to specific examples. However, the embodiments of the invention are not limited to these specific examples. For example, one skilled in the art may similarly practice the invention by appropriately selecting specific configurations of components included in the semiconductor light emitting device and the method for manufacturing the semiconductor light emitting device such as the first semiconductor layer, the second semiconductor layer, the light emitting layer, the stacked body, the optical layer, the optical member, the multilayered film, the first to third layers, the first electrode, the pad portion, the growth substrate, the stacked film, the first semiconductor film, the second semiconductor film, the light emitting film, the workpiece, etc., from known art; and such practice is within the scope of the invention to the extent that similar effects are obtained.

Further, any two or more components of the specific examples may be combined within the extent of technical feasibility and are included in the scope of the invention to the extent that the purport of the invention is included.

Moreover, all semiconductor light emitting devices and all methods for manufacturing same practicable by an appropriate design modification by one skilled in the art based on the semiconductor light emitting device and the method for manufacturing same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device, comprising:
a stacked body including
a first semiconductor layer of a first conductivity type,
a second semiconductor layer of a second conductivity type separated from the first semiconductor layer in a first direction, and
a light emitting layer provided between the first semiconductor layer and the second semiconductor layer; and
an optical member stacked with the stacked body in the first direction, the optical member being light-transmissive,
a length of the optical member in the first direction being longer than a length of the first semiconductor layer in the first direction,
a surface area of the optical member projected onto a plane perpendicular to the first direction being less than a surface area of the stacked body projected onto the plane,
at least a portion of the optical member including Al,
an Al composition ratio of the at least a portion of the optical member being higher than an Al composition ratio of the stacked body.

2. The device according to claim 1, wherein
the optical member includes a multilayered film,
the multilayered film includes at least a first layer and a second layer,
the second layer is provided between the first layer and the stacked body, and
an Al composition ratio of the first layer is higher than an Al composition ratio of the second layer.

3. The device according to claim 2, wherein
the multilayered film further includes a third layer,
the third layer is provided between the second layer and the stacked body, and
the Al composition ratio of the second layer is higher than an Al composition ratio of the third layer.

4. The device according to claim 2, wherein the optical member includes a plurality of the multilayered films stacked in the first direction.

5. The device according to claim 1, wherein the optical member includes at least one selected from AlN, AlGaN, and GaN.

6. The device according to claim 1, wherein
the optical member has a surface facing a side opposite to the stacked body,
an unevenness is provided in the surface,
the stacked body has a light extraction surface facing toward the optical member, and
an unevenness is provided in the light extraction surface.

7. The device according to claim 6, wherein the unevenness provided in the surface of the optical member and the unevenness provided in the light extraction surface are larger than a wavelength of light emitted from the light emitting layer.

8. The device according to claim 1, wherein
the optical member has a side surface crossing the plane, and
the side surface is tilted with respect to the first direction.

9. The device according to claim 8, wherein an angle between the side surface and the plane is not less than 30° and not more than 60°.

10. The device according to claim 1, wherein the optical member has a first portion having a frame-like configuration.

11. The device according to claim 10, wherein the first portion is provided along an outer edge of the first semiconductor layer when projected onto the plane.

12. The device according to claim 10, wherein the optical member further has a second portion configured to partition a region inside the first portion.

13. The device according to claim 10, further comprising a first electrode electrically connected to the first semiconductor layer,
the first electrode having a frame-like configuration along an inner side of the optical member when projected onto the plane.

14. The device according to claim 13, wherein
the first electrode has a pad portion used when providing an interconnect to the outside, and
the pad portion is disposed outside the optical member.

15. A method for manufacturing a semiconductor light emitting device, comprising:
preparing a workpiece including
a growth substrate,
a stacked film provided on the growth substrate, the stacked film including:
a first semiconductor film of a first conductivity type;
a second semiconductor film of a second conductivity type separated from the first semiconductor film in a stacking direction of the growth substrate and the stacked film; and
a light emitting film provided between the first semiconductor film and the second semiconductor film, and
a buffer unit provided between the growth substrate and the stacked film, at least a portion of the buffer unit including Al, an Al composition ratio of the at least a portion of the buffer unit being higher than an Al composition ratio of the stacked film;
removing the growth substrate; and
forming an optical member from the buffer unit, the forming of the optical member being characterized in that a length of the optical member in the stacking direction is longer than a length of the first semiconductor film in the stacking direction, a surface area of the optical member projected onto a plane perpendicular to the stacking direction is less than a surface area of the stacked film projected onto the plane, at least a portion of the optical member includes Al, and an Al composition ratio of the at least a portion of the optical member is higher than an Al composition ratio of the stacked film.

16. The method according to claim 15, wherein the forming of the optical member from the buffer unit includes removing a portion of the buffer unit by dry etching.

17. The method according to claim 16, wherein an etching gas of the dry etching includes at least one selected from Cl₂ gas, Ar gas, and a gas mixture of Cl₂ gas and Ar gas.

18. The method according to claim 15, wherein
the optical member has a surface facing a side opposite to the stacked film,
the stacked film has a light extraction surface facing a direction from the stacked film toward the optical member, and
the forming of the optical member from the buffer unit further includes forming an unevenness in the surface of the optical member and in the light extraction surface.

19. The method according to claim 18, wherein the forming of the unevenness includes at least one selected from dry etching and wet etching.

20. The method according to claim 19, wherein
an etching gas of the dry etching of the forming of the unevenness includes Cl₂ gas, and
an etchant of the wet etching of the forming of the unevenness includes a KOH aqueous solution.
